(19) United States
(12) Patent Application Publication
(10) Pub. No.: US 2023/0020962 A1
(43) Pub. Date: Jan. 19, 2023

(54) METHOD FOR PREPARING PEROVSKITE ELECTRONIC DEVICE

(71) Applicant: Research & Business Foundation Sungkyunkwan University, Suwon-si (KR)

(72) Inventors: Hyun Suk JUNG, Seoul (KR); Gill Sang HAN, Anyang-si (KR); Oh Yeong GONG, Bucheon-si (KR); Min Kyeong SEO, Suwon-si (KR); ChangHwun SOHN, Busan (KR); Jin Hyuk CHOI, Suwon-si (KR); SangMyeong LEE, Gimhae-si (KR)

(73) Assignee: Research & Business Foundation Sungkyunkwan University, Suwon-si (KR)

(21) Appl. No.: 17/852,972

(22) Filed: Jun. 29, 2022

(30) Foreign Application Priority Data
Jul. 8, 2021 (KR) 10-2021-0089523

(51) Int. Cl. H01G 9/20; H01G 9/00

(52) U.S. Cl. CPC H01G 9/2009; H01G 9/2031; H01G 9/0036

(57) ABSTRACT

Provided is a method for preparing a perovskite electronic device including steps of: forming an electron transport layer and a second light absorption layer including a perovskite material each independently on a first substrate and a second substrate; forming a first light absorption layer including a perovskite material on the electron transport layer; coating a solvent on the surface of the first light absorption layer and the second light absorption layer; bonding the second light absorption layer on the first light absorption layer; removing the second substrate; forming a hole transport layer on the second light absorption layer; and forming an electrode on the hole transport layer.

### FIELD

The present disclosure relates to a method of preparing a perovskite electronic device.

### DESCRIPTION OF THE RELATED ART

A perovskite electronic device is an electronic device using a material having a perovskite structure as a light absorber, and has advantages of high photoelectric conversion efficiency, low manufacturing cost, and enabling low-temperature process and low-cost solution process. Accordingly, the perovskite electronic device is attracting attention as a material that can be applied to various fields such as solar cells, memory devices, light emitting devices, and solid-state batteries.

However, due to a stability problem of a perovskite light absorption layer, there are many problems in performing an additional process above the perovskite light absorption layer. When using a chemical lamination process, methods and materials that do not damage the perovskite light absorption layer are limited, and during a physical lamination process, there are many defects at an interface due to the roughness of the surface of the light absorption layer.

Therefore, there is a need for a method of increasing the degree of freedom in selecting upper material and process of the perovskite light absorption layer by controlling the surface of the perovskite light absorption layer.

Korean Patent Registration No. 10-2121413 relates to a perovskite solar cell with improved photoelectric conversion efficiency due to introduction of an interfacial layer between a photoactive layer and a hole transport layer, and a preparation method thereof. However, in Korean Patent Registration No. 10-2121413, there is no mention about reducing the surface roughness by controlling the surface of the photoactive layer.

### CONTENT OF THE INVENTION

### Problem to be Solved

An object to be achieved by the present disclosure is to provide a method for preparing a perovskite electronic device capable of controlling a surface by coating a solvent on the surface of a perovskite light absorption layer and including the perovskite light absorption layer having a multi-layer structure.

Another object to be achieved by the present disclosure is to provide a perovskite electronic device prepared by the preparation method.

Yet another object to be achieved by the present disclosure is to provide a perovskite solar cell including the perovskite electronic device.

Still another object to be achieved by the present disclosure is to provide a memory device including the perovskite electronic device.

Objects of the present disclosure are not limited to the above-mentioned objects, and other objects, which are not mentioned above, can be clearly understood by those skilled in the art from the following descriptions.

### Problem Solving Means

As a technical means for achieving the above technical task, according to a first aspect of the present disclosure, there is provided a method for preparing a perovskite electronic device including steps of forming an electron transport layer and a second light absorption layer including a perovskite material each independently on a first substrate and a second substrate; forming a first light absorption layer including a perovskite material on the electron transport layer; coating a solvent on the surface of the first light absorption layer and/or the second light absorption layer; bonding the second light absorption layer on the first light absorption layer; removing the second substrate; forming a hole transport layer on the second light absorption layer; and forming an electrode on the hole transport layer.

According to an exemplary embodiment of the present disclosure, the surface roughness of the first light absorption layer and the second light absorption layer may be reduced by coating the solvent, but it is not limited thereto.

According to an exemplary embodiment of the present disclosure, the bonding strength of the first light absorption layer and the second light absorption layer may be increased by coating the solvent, but it is not limited thereto.

According to an exemplary embodiment of the present disclosure, the solvent may have a polarity of 2 to 6, but it is not limited thereto.

According to an exemplary embodiment of the present disclosure, the coating may be performed by a method selected from the group consisting of spin coating, bar coating, inkjet printing, nozzle printing, spray coating, slot die coating, gravure printing, screen printing, electrohydrodynamic jet printing, electrospray, and combinations thereof, but it is not limited thereto.

According to an exemplary embodiment of the present disclosure, the bonding may be performed by a hot-pressing process using a machining pressure of a manpower press and a power press, but it is not limited thereto.

According to an exemplary embodiment of the present disclosure, the solvent may include at least one selected from the group consisting of isopropyl alcohol, tert-butyl alcohol, acetonitrile, toluene, ether, chlorobenzene, ethanol, acetone, and combinations thereof, but it is not limited thereto.

According to an exemplary embodiment of the present disclosure, the substrate may include at least one selected from the group consisting of FTO, ITO, IZO, ZnO—Ga₂O₃, ZnO—Al₂O₃, SnO₂—Sb₂O₃, and combinations thereof, but it is not limited thereto.

According to an exemplary embodiment of the present disclosure, the electron transport layer may include at least one selected from the group consisting of SnO₂, TiO₂, ZrO, Al₂O₃, ZnO, WO₃, Nb₂O₅, TiSrO₃, and combinations thereof, but it is not limited thereto.

According to an exemplary embodiment of the present disclosure, the light absorption layer may each independently include a perovskite material represented by the following

Chemical Formula 1 or 2, but it is not limited thereto:

RMX₃ [Chemical Formula 1]

R₄MX₆ [Chemical Formula 2]

(In Chemical Formulas 1 and 2 above,

R is an alkali metal, and a C₁₋₂₄ is substituted or unsubstituted alkyl group, and when R is substituted, the substituent is an amino group, a hydroxyl group, a cyano group, a halogen group, a nitro group, or a methoxy group,

M includes a metal cation selected from the group consisting of Pb, Sn, Ge, Cu, Ni, Co, Fe, Mn, Cr, Pd, Cd, Yb, and combinations thereof, and

X includes a halide anion or a chalcogenide anion).

According to an exemplary embodiment of the present disclosure, the hole transport layer may include at least one at least one selected from the group consisting of Spiro-OMeTAD, PEDOT:PSS, G-PEDOT, PANI:PSS, PANI:CSA, PDBT, P3HT, PCPDTBT, PCDTBT, PTAA, MoO₃, V₂O₅, NiO, WO₃, CuI, CuSCN, and combinations thereof, but it is not limited thereto.

According to an exemplary embodiment of the present disclosure, the electrode may include at least one selected from the group consisting of Au, Ag, Pt, Ni, Cu, In, Ru, Pd, Rh, Mo, Ir, Os, C, a conductive polymer, and combinations thereof, but it is not limited thereto.

According to a second aspect of the present disclosure, there is provided a perovskite electronic device including a substrate; an electron transport layer formed on the substrate; a perovskite light absorption layer formed on the electron transport layer; a hole transport layer formed on the perovskite light absorption layer; and an electrode formed on the hole transport layer, in which the perovskite light absorption layer has a multi-layer structure, and the solvent is coated between the layers.

According to a third aspect of the present disclosure, there is provided a perovskite solar cell including the perovskite electronic device according to the second aspect of the present disclosure.

According to a fourth aspect of the present disclosure, there is provided a memory device including the perovskite electronic device according to the second aspect of the present disclosure.

The above-mentioned technical solutions are merely exemplary and should not be construed as limiting the present disclosure. In addition to the above-described exemplary embodiments, additional exemplary embodiments may exist in the drawings and detailed description of the invention.

### Effects of the Invention

According to the present disclosure, in a method for preparing a perovskite electronic device, a solvent is coated on the surface of a perovskite light absorption layer to dissolve the surface of the perovskite light absorption layer and a grain boundary, thereby reducing the surface roughness. As a result, it is easy to additionally laminate a perovskite light absorption layer or other materials, etc. above the perovskite light absorption layer, and it is possible to prepare a perovskite light absorption layer having a multi-layer structure with minimal defects at the interface.

In addition, a solution is coated on the surface of the perovskite light absorption layer to induce chemical binding between the light absorption layers and increase the bonding strength, and accordingly, the degree of freedom may be increased in the selection of upper material and process of perovskite.

In addition, it is possible to prepare a perovskite light absorption layer having a multi-layer structure with minimal defects without being limited to the preparing area or the thickness of a thin film.

The effects according to the present disclosure are not limited to the effects exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a flowchart of a method for preparing a perovskite electronic device according to an exemplary embodiment of the present disclosure;

FIG. 2 is a schematic diagram of a method for preparing a perovskite electronic device according to an exemplary embodiment of the present disclosure;

FIG. 3 is a schematic diagram of a perovskite electronic device according to an exemplary embodiment of the present disclosure;

FIG. 4 is surface electron microscope images of a perovskite light absorption layers in Example of the present disclosure and Comparative Example;

FIG. 5 is a graph showing results of X-ray diffraction analysis of the perovskite light absorption layers in Example of the present disclosure and Comparative Example;

FIG. 6 is surface roughness images of the perovskite light absorption layers in Example of the present disclosure and Comparative Example.

FIG. 7 illustrates cross-sectional images of the perovskite light absorption layers according to Example of the present disclosure and Comparative Example which are laminated in a multilayer;

FIG. 8 is a voltage-current density graph of a perovskite solar cell according to Experimental Example of the present disclosure;

FIG. 9 is a graph of measuring photoelectric conversion efficiency in the perovskite solar cell according to Experimental Example of the present disclosure;

FIG. 10 is a voltage-current density graph of a perovskite solar cell according to Experimental Example of the present disclosure; and

FIG. 11 is a result illustrating polarities of various polar solvents that may be used when coating the surface of a perovskite light absorption layer according to Experimental Example of the present disclosure.

### DETAILED DESCRIPTION OF THE EMBODIMENT

Hereinafter, exemplary embodiments of the present disclosure will be described in detail so as to be easily implemented by those skilled in the art, with reference to the accompanying drawings.

However, the present disclosure may be embodied in many different forms and is not limited to the exemplary embodiments to be described herein. In addition, parts not related with the description have been omitted in order to clearly describe the present disclosure in the drawings and throughout this specification, like reference numerals designate like elements.

Further, throughout this specification, when a certain part is “connected” with the other part, it is meant that the certain part may be “directly connected” with the other part and “electrically connected” with the other part with another element interposed therebetween.

Throughout this specification, it will be understood that when a certain member is located “on”, “above”, “at the top of”, “under”, “below”, and “at the bottom of” the other member, a certain member is in contact with the other member and another member may also be present between the two members.

Throughout this specification, when a certain part “comprises” a certain component, unless otherwise disclosed to the contrary, it is meant that the part may further comprise another component without excluding another component.

The terms “about”, “substantially”, and the like to be used in this specification are used as a numerical value or a value close to the numerical value when inherent manufacturing and material tolerances are presented in the stated meaning, and used to prevent an unscrupulous infringer from unfairly using disclosed contents in which precise or absolute numerical values are mentioned to help in the understanding of the present disclosure. Throughout this specification, the term “step to” or “step of” does not mean “step for”.

Throughout this specification, the term “combinations thereof” included in the expression of the Markush form means one or more mixtures or combinations selected from the group consisting of components described in the expression of the Markush form, and means to include at least one selected from the group consisting of the components.

Throughout the present disclosure, “A and/or B” means “A or B, or A and B”.

Hereinafter, a method of preparing a perovskite electronic device of the present disclosure will be described in detail with reference to exemplary embodiments, Examples, and drawings. However, the present disclosure is not limited to these exemplary embodiments, Examples, and drawings.

According to a first aspect of the present disclosure, there is provided a method for preparing a perovskite electronic device including steps of forming an electron transport layer and a second light absorption layer including a perovskite material each independently on a first substrate and a second substrate; forming a first light absorption layer including a perovskite material on the electron transport layer; coating a solvent on the surface of the first light absorption layer and/or the second light absorption layer; bonding the second light absorption layer on the first light absorption layer; removing the second substrate; forming a hole transport layer on the second light absorption layer; and forming an electrode on the hole transport layer.

A conventional perovskite light absorption layer has a problem in that when using a chemical lamination process, methods and materials that do not damage the perovskite light absorption layer are limited, and when performing a physical lamination process, many defects exist at an interface due to the roughness of the surface of the light absorption layer.

However, in the method for preparing the perovskite electronic device according to the present disclosure, a solvent is coated on the surface of the perovskite light absorption layer to dissolve the surface of the perovskite light absorption layer and a grain boundary, thereby reducing the surface roughness.

As a result, it is easy to additionally laminate a perovskite light absorption layer or other materials, etc. above the perovskite light absorption layer, and it is possible to prepare a perovskite light absorption layer having a multi-layer structure with minimal defects at the interface.

In addition, a solution is coated on the surface of the perovskite light absorption layer to induce chemical binding between the light absorption layers and increase the bonding strength, and accordingly, the degree of freedom may be increased in the selection of upper material and process of perovskite.

In addition, it is possible to prepare a perovskite light absorption layer having a multi-layer structure with minimal defects without being limited to the preparing area or the thickness of a thin film.

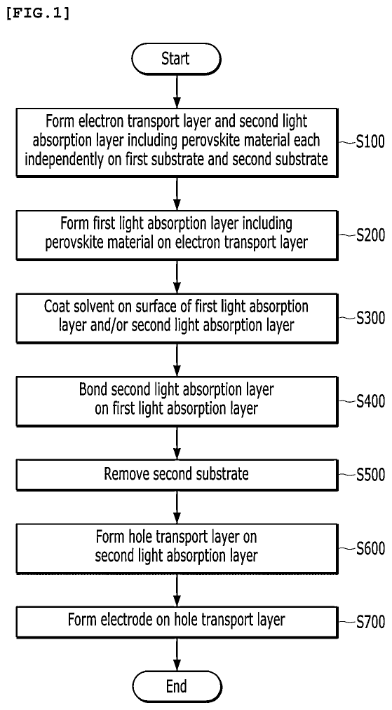

Hereinafter, the method for preparing the perovskite electronic device according to the exemplary embodiment of the present disclosure will be described with reference to FIGS. 1 to 3.

FIG. 1 is a flowchart of the method for preparing the perovskite electronic device according to the exemplary embodiment of the present disclosure.

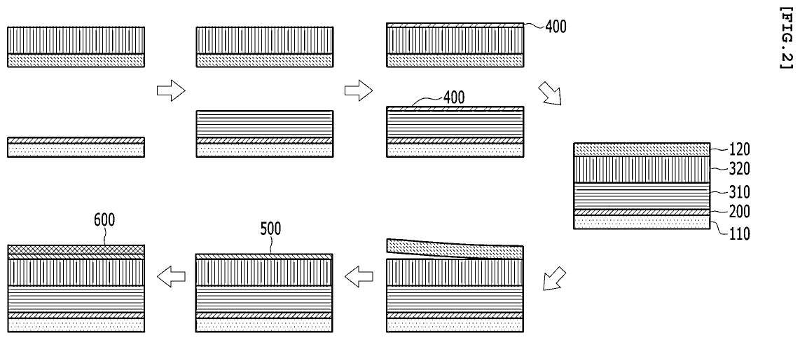

FIG. 2 is a schematic diagram of the method for preparing the perovskite electronic device according to the exemplary embodiment of the present disclosure.

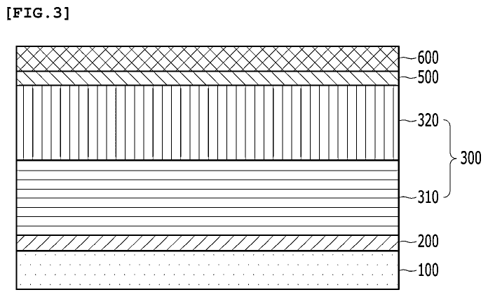

FIG. 3 is a schematic diagram of a perovskite electronic device according to an exemplary embodiment of the present disclosure.

First, an electron transport layer 200 and a second light absorption layer 320 including a perovskite material are independently formed on a first substrate 110 and a second substrate 120 (S100).

According to an exemplary embodiment of the present disclosure, a substrate 100 may include at least one selected from the group consisting of FTO, ITO, IZO, ZnO—Ga₂O₃, ZnO—Al₂O₃, SnO₂—Sb₂O₃, and combinations thereof, but is not limited thereto.

The first substrate 110 and the second substrate 120 may be the same substrate or different substrates, and use a flexible substrate and the like in addition to a transparent conductive substrate, but are not limited thereto.

According to an exemplary embodiment of the present disclosure, the electron transport layer 200 may include at least one selected from the group consisting of SnO₂, TiO₂, ZrO, Al₂O₃, ZnO, WO₃, Nb₂O₅, TiSrO₃, and combinations thereof, but is not limited thereto.

Next, a first light absorption layer 310 including a perovskite material is formed on the electron transport layer 200 (S200).

According to an exemplary embodiment of the present disclosure, the light absorption layer 300 may each independently include a perovskite material represented by the following Chemical Formula 1 or 2, but is not limited thereto:

RMX₃ [Chemical Formula 1]

R₄MX₆ [Chemical Formula 2]

(In Chemical Formulas 1 and 2 above,

R is an alkali metal, and a C₁₋₂₄ is substituted or unsubstituted alkyl group, and when R is substituted, the substituent is an amino group, a hydroxyl group, a cyano group, a halogen group, a nitro group or a methoxy group,

M includes a metal cation selected from the group consisting of Pb, Sn, Ge, Cu, Ni, Co, Fe, Mn, Cr, Pd, Cd, Yb, and combinations thereof, and

X includes a halide anion or a chalcogenide anion).

The first light absorption layer 310 and the second light absorption layer 320 may include the same perovskite material or different perovskite materials, but are not limited thereto.

Next, a solvent 400 is coated on the surface of the first light absorption layer 310 and/or the second light absorption layer 320 (S300).

According to the exemplary embodiment of the present disclosure, the surface roughness of the first light absorption layer 310 and/or the second light absorption layer 320 may be reduced by coating the solvent 400, but it is not limited thereto.

In the method for preparing the perovskite electronic device according to the present disclosure, the solvent is coated on the surface of the perovskite light absorption layer to dissolve the surface of the perovskite light absorption layer and a grain boundary, thereby reducing the surface roughness. As a result, it is easy to additionally laminate a perovskite light absorption layer or other materials, etc. above the perovskite light absorption layer, and it is possible to prepare a perovskite light absorption layer having a multi-layer structure with minimal defects at the interface.

According to an exemplary embodiment of the present disclosure, the solvent 400 may have a polarity of 2 to 6, but is not limited thereto.

When coating the surface of the perovskite light absorption layer using a solvent having a polarity greater than 6, damage to the perovskite light absorption layer may occur, but the present disclosure is not limited thereto.

According to an exemplary embodiment of the present disclosure, the solvent 400 may include at least one selected from the group consisting of isopropyl alcohol, tert-butyl alcohol, acetonitrile, toluene, ether, chlorobenzene, ethanol, acetone, and combinations thereof, but is not limited thereto.

According to an exemplary embodiment of the present disclosure, the coating may be performed by a method selected from the group consisting of spin coating, bar coating, inkjet printing, nozzle printing, spray coating, slot die coating, gravure printing, screen printing, electrohydrodynamic jet printing, electrospray, and combinations thereof, but is not limited thereto.

The solvent 400 may not remain on the surfaces of the first light absorption layer 310 and the second light absorption layer 320 by evaporation after being coated on the surface of the light absorption layer, but is not limited thereto.

Next, the second light absorption layer 320 is bonded on the first light absorption layer 310 (S400).

According to the exemplary embodiment of the present disclosure, the bonding strength of the first light absorption layer 310 and the second light absorption layer 320 may be increased by coating the solvent 400, but it is not limited thereto.

In the method for preparing the perovskite electronic device of the present disclosure, the solution is coated on the surface of the perovskite light absorption layer to induce chemical binding between the light absorption layers and increase the bonding strength, and accordingly, the degree of freedom may be increased in the selection of upper material and process of perovskite.

According to the exemplary embodiment of the present disclosure, the bonding may be performed by a hot-pressing process using a machining pressure of a manpower press and a power press, but is not limited thereto.

Next, the second substrate 120 is removed (S500).

Next, a hole transport layer 500 is formed on the second light absorption layer 320 (S600).

According to the exemplary embodiment of the present disclosure, the hole transport layer 500 may include at least one selected from the group consisting of Spiro-OMeTAD, PEDOT:PSS, G-PEDOT, PANI:PSS, PANI:CSA, PDBT, P3HT, PCPDTBT, PCDTBT, PTAA, MoO₃, V₂O₅, NiO, WO₃, CuI, CuSCN, and combinations thereof, but is not limited thereto.

Finally, an electrode 600 is formed on the hole transport layer 500 (S700).

According to the exemplary embodiment of the present disclosure, the electrode 600 may include at least one selected from the group consisting of Au, Ag, Pt, Ni, Cu, In, Ru, Pd, Rh, Mo, Ir, Os, C, a conductive polymer, and combinations thereof, but is not limited thereto.

In addition, a second aspect of the present disclosure provides a perovskite electronic device including a substrate 100; an electron transport layer 200 formed on the substrate 100; a perovskite light absorption layer 300 formed on the electron transport layer 200; a hole transport layer 500 formed on the perovskite light absorption layer 300; and an electrode 600 formed on the hole transport layer 500, in which the perovskite light absorption layer 300 has a multi-layer structure and a solvent 400 is coated between the layers.

With respect to the perovskite electronic device according to the second aspect of the present disclosure, the detailed description of parts duplicated with the first aspect of the present disclosure has been omitted, but even if the description is omitted, the contents disclosed in the first aspect of the present disclosure may be equally applied to the second aspect of the present application.

In the perovskite electronic device according to the present disclosure, the solvent is coated on the surface of the perovskite light absorption layer to dissolve the surface of the perovskite light absorption layer and a grain boundary, thereby reducing the surface roughness. As a result, it is easy to additionally laminate a perovskite light absorption layer or other materials, etc. above the perovskite light absorption layer, and it is possible to prepare a perovskite light absorption layer having a multi-layer structure with minimal defects at the interface.

In addition, a solution is coated on the surface of the perovskite light absorption layer to induce chemical binding between the light absorption layers and increase the bonding strength, and accordingly, the degree of freedom may be increased in the selection of upper material and process of perovskite.

The perovskite electronic device according to the present disclosure may be used in various fields, such as perovskite solar cells, memory devices, light emitting devices, memristors, photodiodes, and phototransistors.

In addition, a third aspect of the present disclosure provides a perovskite solar cell including the perovskite electronic device according to the second aspect of the present disclosure.

With respect to the perovskite solar cell according to the third aspect of the present disclosure, the detailed description of parts duplicated with the second aspect of the present disclosure has been omitted, but even if the description is omitted, the contents disclosed in the second aspect of the present disclosure may be equally applied to the third aspect of the present application.

In addition, a fourth aspect of the present disclosure provides a memory device including the perovskite electronic device according to the second aspect of the present disclosure.

With respect to the memory device according to the fourth aspect of the present disclosure, the detailed description of parts duplicated with the second aspect of the present disclosure has been omitted, but even if the description is omitted, the contents disclosed in the second aspect of the present disclosure may be equally applied to the fourth aspect of the present application.

Hereinafter, the present disclosure will be described in more detail with reference to the following Examples, but the following Examples are only for illustrative purposes and are not intended to limit the scope of the present disclosure.

### Example Preparation of Perovskite Electronic Device

First, F-doped SnO₂ (FTO) as a first substrate and Sn-doped In₂O₃ (ITO)/polyethylene naphthalate (PEN) as a second substrate were prepared.

Thereafter, chemical bath deposition was performed on the first substrate (FTO) with 0.165 M of a TiCl₄ solution at 70° C. for 45 minutes and 30 seconds to form a very thin film, and then heat treatment was performed at 150° C. for 70 minutes to form a metal oxide electron transport layer (TiO₂) (TiO₂/FTO).

Next, a perovskite light absorption layer precursor solution having a composition of (FAPbI₃)_{0.90}(MAPbBr₃)_{0.05}(CsPbI₃)_{0.05} at a concentration of 1.3 M was prepared by dissolving 16.9 mg of CsI, 201.2 mg of FAI, 569.3 mg of PbI₂, 7.3 mg of MABr, 23.9 mg of PbBr₂, and 27.3 mg of MACl in DMF:DMSO (7:3, v/v, total 1 ml). The perovskite light absorption layer precursor solution at the concentration of 1.3 M was spin-coated on the second substrate (ITO/PEN) and then heat-treated at a temperature of 100° C. for 40 minutes to form a second perovskite light absorption layer (FA_{0.90}MA_{0.5}Cs_{0.05}PbI_{2.85}Br_{0.15}, Pev) (Pev2/ITO).

Next, a perovskite light absorption layer precursor solution having a composition of (FAPbI₃)_{0.90}(MAPbBr₃)_{0.05}(CsPbI₃)_{0.05} at a concentration of 0.8 M was prepared by dissolving 10.4 mg of CsI, 123.8 mg of FAI, 350.4 mg of PbI₂, 4.5 mg of MABr, 14.7 mg of PbBr₂, and 16.8 mg of MACl in DMF:DMSO (7:3, v/v, total 1 ml). The perovskite light absorption layer precursor solution at the concentration of 0.8 M was spin-coated on the first substrate (TiO₂/FTO) formed with the electron transport layer and then heat-treated at a temperature of 150° C. for 10 minutes to form a first perovskite light absorption layer (FA_{0.90}MA_{0.05}Cs_{0.05}PbI_{2.85}Br_{0.15}, Pev) (Pev1/TiO₂/FTO).

Next, isopropyl alcohol, tert-butyl alcohol, and acetonitrile were spin-coated on the surface of the perovskite light absorption layer of Pev1/TiO₂/FTO (Sol'n/Pev1/TiO₂/FTO).

Next, a hot-pressing process was performed near a perovskite phase transition temperature at a pressure of less than perovskite young's modulus to bond the first perovskite light absorption layer and the second perovskite light absorption layer (PEN/ITO/Pev2/Sol'n/Pev1/TiO₂/FTO).

Next, the ITO/PEN substrate on the FTO substrate is removed (Pev2/Sol'n/Pev1/TiO₂/FTO).

Next, 72.3 mg of Spiro-OMeTAD was dissolved in 1 ml of chlorobenzene to form a Spiro-OMeTAD solution. Thereafter, 180 mg of Li-TFSI was dissolved in 250 ml of acetonitrile to form a Li-TFSI solution. A hole transport layer material solution was prepared by dissolving 28.8 μl of 4-tert-butylpyridine and 17.6 μl of the Li-TFSI solution in the Spiro-OMeTAD solution. A hole transport layer (Spiro-OMeTAD) was formed by spin-coating the hole transport layer material solution (Spiro-OMeTAD/Pev2/Sol'n/Pev1/TiO₂/FTO).

Next, gold (Au) was deposited on the surface of the hole transport layer to be a thickness of 50 nm or more under a high vacuum (10⁻⁶) to form an electrode (Au/Spiro-OMeTAD/Pev2/Sol'n/Pev1/TiO₂/FTO).

### Comparative Example 1

A perovskite electronic device was prepared in the same manner as in Example 1, without performing the process of coating the solution on the surface of the perovskite light absorption layer.

### Comparative Example 2 Perovskite Electronic Device Prepared by One-Step Process

First, an F-doped SnO₂ (FTO) substrate was prepared.

Next, chemical bath deposition was performed on the substrate (FTO) with 0.165 M of a TiCl₄ solution at 70° C. for 45 minutes and 30 seconds to form a very thin film, and then heat treatment was performed at 150° C. for 70 minutes to form a metal oxide electron transport layer (TiO₂) (TiO₂/FTO).

Next, a perovskite light absorption layer precursor solution having a composition of (FAPbI₃)_{0.90}(MAPbBr₃)_{0.05}(CsPbI₃)_{0.05} at a concentration of 1.61 M was prepared by dissolving 20.9 mg of CsI, 249.2 mg of FAI, 705.1 mg of PbI₂, 9.0 mg of MABr, 29.5 mg of PbBr₂, and 33.8 mg of MACl in DMF:DMSO (7:3, v/v, total 1 ml). The perovskite light absorption layer precursor solution at the concentration of 1.61 M was spin-coated on the substrate (TiO₂/FTO) formed with the electron transport layer and then heat-treated at a temperature of 150° C. for 10 minutes to form a perovskite light absorption layer (FA_{0.90}MA_{0.05}Cs_{0.05}PbI_{2.85}Br_{0.15}, Pev) (Pev1/TiO₂/FTO).

Next, 72.3 mg of Spiro-OMeTAD was dissolved in 1 ml of chlorobenzene to form a Spiro-OMeTAD solution. Thereafter, 180 mg of Li-TFSI was dissolved in 250 ml of acetonitrile to form a Li-TFSI solution. A hole transport layer material solution was prepared by dissolving 28.8 μl of 4-tert-butylpyridine and 17.6 μl of the Li-TFSI solution in the Spiro-OMeTAD solution. A hole transport layer (Spiro-OMeTAD) was formed by spin-coating the hole transport layer material solution (Spiro-OMeTAD/Pev/TiO₂/FTO).

Next, gold (Au) was deposited on the surface of the hole transport layer to be a thickness of 50 nm or more under a high vacuum (10⁻⁶) to form an electrode (Au/Spiro-OMeTAD/Pev/TiO₂/FTO).

### Experimental Example 1 Comparison of Surfaces

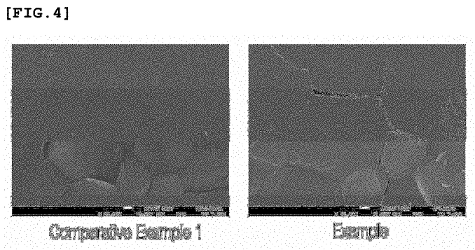

FIG. 4 illustrates surface electron microscope images of perovskite light absorption layers of Example of the present disclosure and Comparative Example 1.

Referring to FIG. 4, it can be confirmed that a perovskite light absorption layer treated with a solvent on the surface has a flatter surface than a perovskite light absorption layer in which a grain boundary and the surface are dissolved and the solvent is not treated.

### Experimental Example 2

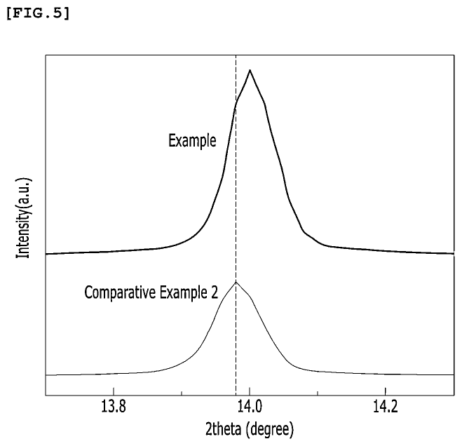

FIG. 5 is a graph showing results of X-ray diffraction analysis of the perovskite light absorption layers in Example of the present disclosure and Comparative Example 2.

Referring to FIG. 5, it can be confirmed that the perovskite light absorption layer (Example) having the laminate structure prepared through a hot-pressing process after treating the solvent on the surface of the perovskite light absorption layer has higher crystallinity than a one-step perovskite light absorption layer (Comparative Example 2) with the same thickness without a laminate structure. It can be confirmed that a uniform pressure is applied to the device through a numerical value shifted at a high angle from 13.98° to 14.00°.

### Experimental Example 3 Confirmation of Surface Roughness and Defects During Lamination

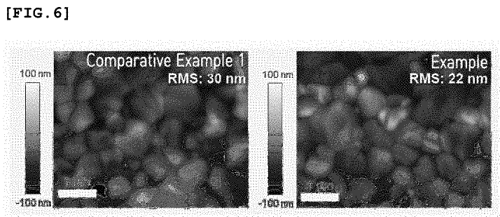

FIG. 6 illustrates surface roughness images of the perovskite light absorption layers in Example of the present disclosure and Comparative Example 1.

Referring to FIG. 6, it can be confirmed that the perovskite light absorption layer (Comparative Example 1) without treating the solvent on the surface has the surface roughness of 30 nm, while the surface roughness of the perovskite light absorption layer (Example) treated with the solvent on the surface is 22 nm. In addition, it can be confirmed that the solvent is treated on the surface to have flat roughness.

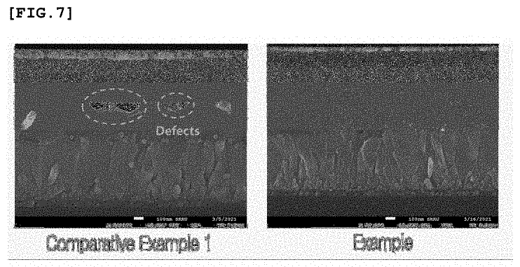

FIG. 7 illustrates cross-sectional images of the perovskite light absorption layers according to Example of the present disclosure and Comparative Example 1 which are laminated in a multilayer.

Referring to FIG. 7, it can be confirmed that defects exist at the interface when the surface of the perovskite light absorption layer is not treated with the solvent. On the other hand, it can be confirmed that when the surface of the perovskite light absorption layer is treated with the solvent, the lamination is performed without defects at the interface.

Therefore, it was confirmed that the interfacial defects could be minimized during the bonding process of the perovskite light absorption layer by having low surface roughness.

### Experimental Example 4 Comparison of Solar Cell Efficiency

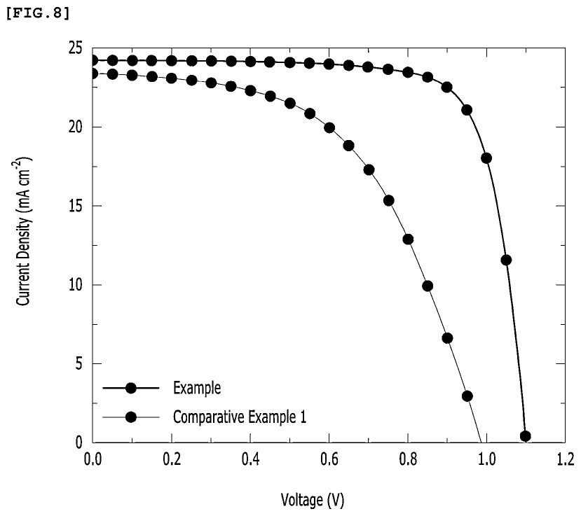

FIG. 8 is a voltage-current density graph of a perovskite solar cell according to Experimental Example of the present disclosure.

Referring to FIG. 8, it can be confirmed that the performance of the device (Example) bonded after solvent treatment is superior to that of the device (Comparative Example 1) bonded without solvent treatment.

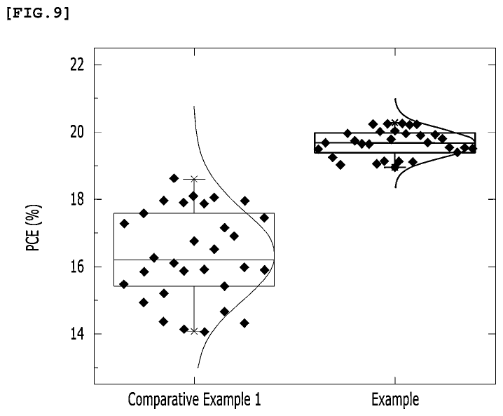

FIG. 9 is a graph of measuring photoelectric conversion efficiency in the perovskite solar cell according to Experimental Example of the present disclosure.

The photoelectric conversion efficiency was measured by measuring 30 solar cells each including the electronic devices of Example and Comparative Example 1. As a result of the measurement, it was confirmed that Example in which the solvent was treated on the surface of the perovskite light absorption layer showed high efficiency with a lower deviation.

Table 1 below is a table showing values obtained by measuring the performance of the perovskite solar cells including the perovskite electronic devices of Example and Comparative Example 1.

TABLE 1

| Samples | JSC | VOC | FF | η (%) |
|---|---|---|---|---|
| Example | 24.22 | 1.10 | 0.76 | 20.26 |
| Comparative | 23.43 | 0.99 | 0.53 | 12.25 |
| Example 1 | | | | |

Referring to Table 1, it can be confirmed that short circuit current density (J_{SC}), open circuit voltage (V_{OC}), curve factor (Fill Factor), and photoelectric conversion efficiency (η (%)) all are high in the solar cell including the perovskite electronic device of Example.

### Experimental Example 5

An experiment was conducted to compare the efficiency of a solar cell including a perovskite light absorption layer laminated using different perovskite materials on a first light absorption layer and a second light absorption layer.

In the experiment, the first light absorption layer was used with perovskite having a composition of FA_{0.80}MA_{0.04}Cs_{0.16}Pb(I_{0.7}Br_{0.3})₃, and the second light absorption layer was used with a composition of FA_{0.90}MA_{0.05}Cs_{0.05}Pb(I_{0.95}Br_{0.05})₃. In the same manner as in the preparation methods of Example and Comparative Example 1, a sample treated with a solvent on the surface of the perovskite light absorption layer and a sample untreated with the solvent were prepared, and the two samples were compared.

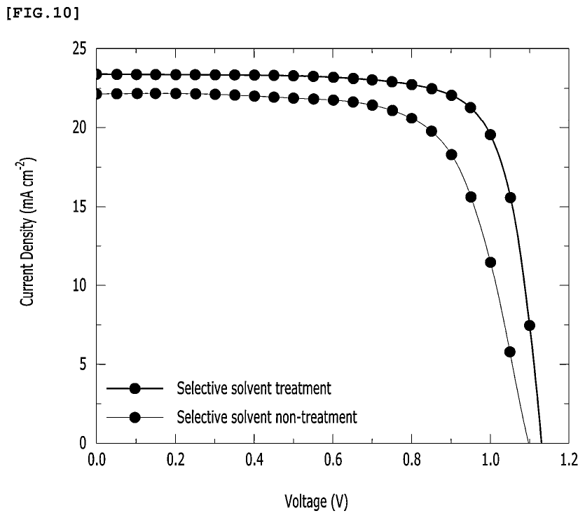

FIG. 10 is a voltage-current density graph of a perovskite solar cell according to Experimental Example of the present disclosure.

Referring to FIG. 10, it can be confirmed that the sample treated with the solvent on the surface exhibits higher efficiency even when perovskite light absorption layers having different compositions are bonded.

The following Table 2 is a table illustrating measured values of the performance of the perovskite solar cell according to Experimental Example of the present disclosure.

TABLE 2

| Samples | JSC | VOC | FF | η (%) |
|---|---|---|---|---|
| Solvent-treated | 23.45 | 1.13 | 0.76 | 20.26 |
| sample | | | | |
| Solvent-untreated | 20.68 | 1.07 | 0.69 | 15.24 |
| sample | | | | |

Referring to Table 2, it was confirmed that the solvent-treated sample had higher performance.

As a result, it could be confirmed that regardless of the composition of the perovskite light absorption layer, an electronic device with higher performance may be prepared by treating the solvent on the surface of the perovskite light absorption layer.

### Experimental Example 6

In the preparation of the perovskite electronic device according to the present disclosure, an experiment was conducted to determine a type of polar solvent that may be coated on the surface of the perovskite light absorption layer.

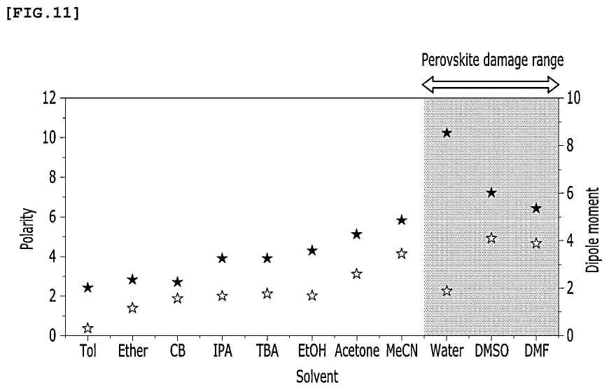

FIG. 11 is result illustrating polarities of various polar solvents that may be used when coating the surface of a perovskite light absorption layer according to Experimental Example of the present disclosure.

Referring to FIG. 11, it could be confirmed that when the coating was performed on the surface of the perovskite light absorption layer using a polar solvent (water, DMSO, DMF) with a polarity of 6 or more, the surface of the perovskite light absorption layer was damaged. Therefore, it could be confirmed that a polar solvent having a polarity of 2 to 6 was used to lower the surface roughness without damaging the surface of the perovskite light absorption layer.

The aforementioned description of the present disclosure is to be exemplified, and it will be understood by those skilled in the art that the present disclosure can be easily modified in other detailed forms without changing the technical spirit or required features of the present disclosure. Therefore, it should be appreciated that the embodiments described above are illustrative in all aspects and are not restricted. For example, respective components described as single types can be distributed and implemented, and similarly, components described to be distributed can also be implemented in a coupled form.

The scope of the present disclosure is represented by appended claims to be described below rather than the detailed description, and it is to be interpreted that the meaning and scope of the claims and all the changes or modified forms derived from the equivalents thereof come within the scope of the present disclosure.

### EXPLANATION OF MARKS

100: substrate
110: first substrate
120: second substrate
200: electron transport layer
300: light absorption layer
310: first light absorption layer
320: second light absorption layer

What is claimed is:

1. A method for preparing a perovskite electronic device comprising steps of:
forming an electron transport layer and a second light absorption layer including a perovskite material each independently on a first substrate and a second substrate;
forming a first light absorption layer including the perovskite material on the electron transport layer;
coating a solvent on a surface of the first light absorption layer and/or the second light absorption layer;
bonding the second light absorption layer on the first light absorption layer;
removing the second substrate;
forming a hole transport layer on the second light absorption layer; and
forming an electrode on the hole transport layer.

2. The method for preparing the perovskite electronic device of claim 1, wherein the solvent is coated to reduce a surface roughness of the first light absorption layer and the second light absorption layer.

3. The method for preparing the perovskite electronic device of claim 1, wherein the solvent is coated to increase a bonding strength of the first light absorption layer and the second light absorption layer.

4. The method for preparing the perovskite electronic device of claim 1, wherein the solvent has a polarity of 2 to 6.

5. The method for preparing the perovskite electronic device of claim 1, wherein the coating is performed by a method selected from the group consisting of spin coating, bar coating, inkjet printing, nozzle printing, spray coating, slot die coating, gravure printing, screen printing, electrohydrodynamic jet printing, electrospray, and combinations thereof.

6. The method for preparing the perovskite electronic device of claim 1, wherein the bonding is performed by a hot-pressing process using a machining pressure of a manpower press and a power press.

7. The method for preparing the perovskite electronic device of claim 1, wherein the solvent is at least one selected from the group consisting of isopropyl alcohol, tert-butyl alcohol, acetonitrile, toluene, ether, chlorobenzene, ethanol, acetone, and combinations thereof.

8. The method for preparing the perovskite electronic device of claim 1, wherein the substrate includes at least one selected from the group consisting of FTO, ITO, IZO, ZnO—Ga₂O₃, ZnO—Al₂O₃, SnO₂—Sb₂O₃, and combinations thereof.

9. The method for preparing the perovskite electronic device of claim 1, wherein the electron transport layer includes at least one selected from the group consisting of SnO₂, TiO₂, ZrO, Al₂O₃, ZnO, WO₃, Nb₂O₅, TiSrO₃, and combinations thereof.

10. The method for preparing the perovskite electronic device of claim 1, wherein the light absorption layer each independently includes the perovskite material represented by the following Chemical Formula 1 or 2:
RMX₃ [Chemical Formula 1]
R₄MX₆ [Chemical Formula 2]
(In Chemical Formulas 1 and 2 above,
R is an alkali metal, and a C₁₋₂₄ is substituted or unsubstituted alkyl group, and when R is substituted, the substituent is an amino group, a hydroxyl group, a cyano group, a halogen group, a nitro group, or a methoxy group,
M includes a metal cation selected from the group consisting of Pb, Sn, Ge, Cu, Ni, Co, Fe, Mn, Cr, Pd, Cd, Yb, and combinations thereof, and
X includes a halide anion or a chalcogenide anion).

11. The method for preparing the perovskite electronic device of claim 1, wherein the hole transport layer includes at least one selected from the group consisting of Spiro-OMeTAD, PEDOT:PSS, G-PEDOT, PANI:PSS, PANI:CSA, PDBT, P3HT, PCPDTBT, PCDTBT, PTAA, MoO₃, V₂O₅, NiO, WO₃, CuI, CuSCN, and combinations thereof.

12. The method for preparing the perovskite electronic device of claim 1, wherein the electrode includes at least one selected from the group consisting of Au, Ag, Pt, Ni, Cu, In, Ru, Pd, Rh, Mo, Ir, Os, C, a conductive polymer, and combinations thereof.

13. A perovskite electronic device comprising:
a substrate;
an electron transport layer formed on the substrate;
a perovskite light absorption layer formed on the electron transport layer;
a hole transport layer formed on the perovskite light absorption layer; and
an electrode formed on the hole transport layer,
wherein the perovskite light absorption layer has a multi-layer structure, and a solvent is coated between the layers.

14. A perovskite solar cell comprising the perovskite electronic device according to claim 13.

15. A memory device comprising the perovskite electronic device according to claim 13.
